(19) United States
(12) Patent Application Publication
(10) Pub. No.: US 2002/0180021 A1
(43) Pub. Date: Dec. 5, 2002

(54) Three-dimension multi-chip stack package technology

(75) Inventors: Chih-Wen Lin, Hsin-Chu City (TW); Chen-Jung Tsai, Tainan City (TW); Jui-Chung Lee, Yun-Lin (TW)

Correspondence Address: POWELL, GOLDSTEIN, FRAZER & MURPHY LLP, P.O. BOX 97223, WASHINGTON, DC, 20090-7223, US

(73) Assignee: MACRONIX INTERNATIONAL CO., LTD.

(21) Appl. No.: 10/132,157

(22) Filed: Apr. 26, 2002

Related U.S. Application Data
(62) Division of application No. 09/872,264, filed on Jun. 1, 2001.

(51) Int. Cl. H01L 21/50

(52) U.S. Cl. 257/686; 438/109

(57) ABSTRACT

The present invention provides a structure and a method for multi-chip stack package. The present invention uses the liquid insulating epoxy to adhere and stack chips. The liquid insulating epoxy is filled the space between chips and metal wires bonded thereon and the liquid insulating epoxy is higher than the high of the arc of those metal wires, so it can increase the reliability of stacking and bonding process. The present invention can stack multi-chip (more than two) bycontrolling the arc height of the wire and the thickness of the chip. The present can easily perform by visible equipment and materials.

### BACKGROUND OF THE INVENTION

1. Field of the Invention

The present invention generally relates to chip package technology, and more particularly relates to a three-dimension multi-chip stack package technology.

2. Description of the Prior Art

In the interest of higher performance and lower cost, increased miniaturization of components and greater packaging density have been the most goals of the electric industry. The density of the IC package is primarily limited by the area available for die mounting and the total height for the IC package. A method of increasing density is to stack die or chips vertically.

U.S. Pat. No. 6,118,176 issued to ASE in 2000 discloses a structure of a stacked chip assembly that only apply to that the bond pad is on the center of the chip. One of the chips is face up and another is face down. It is using a thermal plastic film to attach chips and to adhere the chip and the leadframe. U.S. Pat. No. 5,814,881 issued to LSI in 1998 discloses a structure of a stack integrated chip package and a method of making same, which can only stack two chips. Both of chips are in the same side of the paddle. The bottom chip is face down and is large than the die paddle. The adhesive layer is used epoxy and the upper chip is face up to adhere on the bottom chip. A wire bonding process is used to connect the internal signal. U.S. Pat. No. 5,804,874 issued to Samsung in 1998 discloses a structure of a plurality of lead on chip type semiconductor chips. The patent discloses that chips are adhered on different lead modules and then every lead modules are connected on the below leadframe to increase package density by using a thermal-compressing method. U.S. Pat. No. 5,793,101 issued to Intel in 1998 discloses a method for packaging multiple semiconductor dies. A flexible circuit board is adhesively laminated to both sides of the paddle and two chips are distinguishingly mounted on on the flexible circuit board which on both sides of the paddle. U.S. Pat. No. 5,689,135 issued to Micron in 1997 discloses a multi-die semiconductor die assembly. A LOC type film is used to adhere the bottom chip and the leadframe die paddle. Chips are faced up and the position of wires bonded is at the space between inner leads. U.S. Pat. No. 5,323,060 issued to Micron in 1994 discloses a multi-chips module. Chips are stacked on a substrate in z-direction and faced up. The adhesive layer is used thermoplastic tape. U.S. Pat. No. 5,347,429 issued to Hitachi Ltd in 1994 discloses a plastic-molded-type semiconductor device including a plurality of semiconductor chips. The patent is used an insulating film to be a die pad. The inner lead has special notch and the bond pad of the bottom chip needs a special design according to the inner lead opening. U.S. Pat. No. 5,291,061 issued to Micron in 1994 discloses a structure of a multi-chip stacked die device. Chips are faced up and the thickness of the adhesive layer is depended on the high of the arc of the wire. The patent is used a controlled-thickness thermoplastic-adhesive layer to adhere chips and die paddle.

In the foregoing references, there are still many disadvantages need to overcome. For example, the use of the adhesive film raises the package cost and different directions wires bonding process needs additional tooling cost and more process difficulty.

Currently, there are essentially two kinds of methods for stacking same-size chips. One of the method is stacking chips on both sides of the leadframe paddle and the active side of two chips is in contrary directions. This method needs design a special bond pad for one chip and a reversal process. The process is complicated and not easily controlled. Furthermore, chips are easily damage in stacking processes and the process cost is high. Another method is stacking chips on one side of the leadframe paddle and active sides of chips are in same directions. This method is often used a thermal plastic film to adhere chips, wherein the thermal plastic film has a specific thickness and a area smaller than the chip. However, the thermal plastic adhesive film has a high cost and the process is complicated and difficult controlled, which needs a high-aligned process to avoid damaging chips. Another question is that the thermal plastic adhesive film is a solid material, so the non-insulating adhesive film must have an area smaller than the chip area to for the bonding region. Because the bonding region of the upper chip is midair, it is easy to damage the chip in the bonding process. Furthermore, the normal bonding process need a thicker film to separate the high loop of the wire, so it is difficult to shrink the high to stack more chips (more than three).

### SUMMARY OF THE INVENTION

The primary object of the invention is to integrate same or different dimension chips in a single IC to have a high density characteristic.

Another object of the invention is to integrate different function chips in a single IC module to have a multi-function characteristic.

A further object of the invention is to provide an easy and efficient multi-chip stack package technology, which uses visible equipment and materials.

In order to achieve previous objects of the invention, a method comprises following essential steps is provided. First, a multi-chip paddle having a base surface is provided. Then, a first chip is mounted on the base surface of the multi-chip paddle and an active surface of the first chip is opposed to the base surface of the multi-chip paddle. Next, a plurality of first wires is bonded between the active surface of the first chip and a plurality of leads of the multi-chip paddle. Following, a liquid insulating adhesive layer is formed to completely cover the active surface of the first chip and the first wires bonded thereon, wherein the liquid insulating adhesive layer is higher than a high of an arc of those first wires. Then, a second chip is stacked and aligned on the first chip by using the liquid insulating adhesive layer and an active surface of the second chip is opposed to the base surface of the multi-chip paddle. Last, a plurality of second wires are bonded between the active surface of the second chip and those leads of the multi-chip paddle.

A further object of the invention is to provide a structure for multi-chip stack package. First, a multi-chip paddle has a base surface. Then, a first chip is mounted on the base surface of the multi-chip paddle, wherein an active surface of the first chip is opposed to the base surface of the multi-chip paddle. Next, a plurality of first wires is bonded between the active surface of the first chip and a plurality of leads of the multi-chip paddle. A liquid insulating adhesive layer completely covers the active surface of the first chip and the first wires bonded thereon, wherein the liquid insulating adhesive layer is higher than a high of an arc of those first wires. A second chip is stacked and aligned on the first chip by the liquid insulating adhesive layer, wherein an active surface of the second chip is opposed to the base surface of the multi-chip paddle. Last, a plurality of second wires is bonded between the active surface of the second chip and those leads of the multi-chip paddle.

### BRIEF DESCRIPTION OF THE DRAWINGS

The foregoing aspects and many of the accompanying advantages of this invention will become more readily appreciated as the same becomes better understood by reference to the following detailed description, when taken in conjunction with the accompanying drawings, wherein:

FIG. 1 is the flowchart of the present invention;

FIG. 2, FIG. 3, FIG. 4, and FIG. 5 are the schematic representations of the multi-chip stack package structure, in accordance with the present invention;

FIG. 6A and FIG. 6B are the schematic representations of the multi-chip stack package structure with different sizes or functions, in accordance with the present invention; and

FIG. 7A and FIG. 7B are the schematic representations of the multi-chip stack package structure with different paddles, in accordance with the present invention.

### DESCRIPTION OF THE PREFERRED EMBODIMENT

The embodiments illustrated herein are show in two-dimensional views with various regions having width and depth, it should be clearly understood that these regions are illustrations of only a portion of a single cell of a device, which may include a plurality of such cells arranged in a three-dimensional structure.

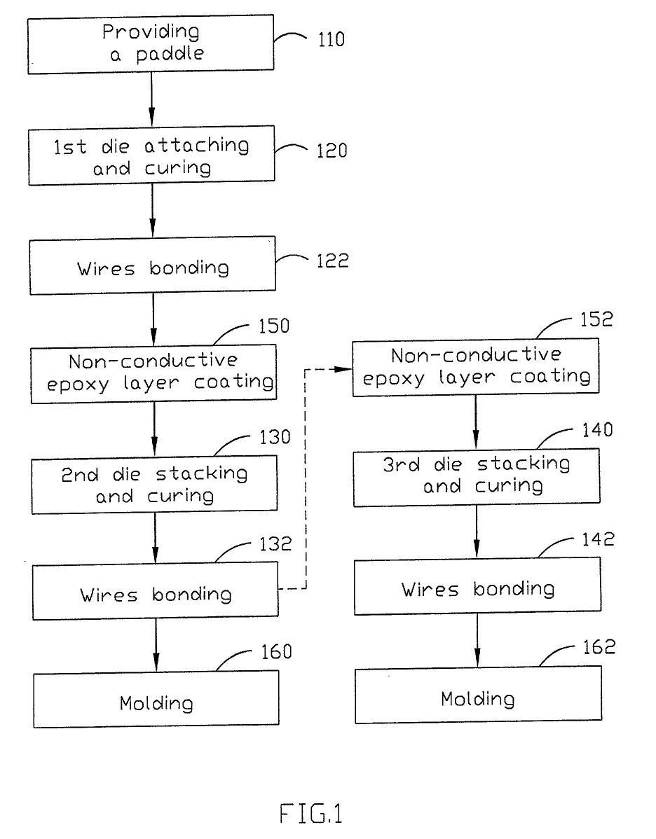

In this invention, a set of process steps and a structure were introduced to form a multi-chip stack package. The method will be detailed explained in a flowchart, as shown in FIG. 1.

First, a multi-chip paddle is provided (step 110). The present invention can use a leadframe type paddle or a substrate type paddle. The substrate type paddle can be selected from the group of an organic substrate, a ceramic substrate, and a metal substrate. The multi-chip paddle has a base surface. Then, a first chip is attached and then cured on the base surface of the multi-chip paddle (step 120). The first chip has an active surface and the active surface is opposed to the base surface of the multi-chip paddle. There may further comprises a adhesive layer to compact the first chip and the multi-chip paddle.

Following, a plurality of first wires are bonded between the active surface of the first chip and a plurality of leads of the multi-chip paddle (step 122). The process of bonding those first wires can be selected from the group of a normal bonding process and a reverse bonding process. Next, a liquid insulating adhesive layer is formed on the first chip (step 150) to cover the first chip and those first wires which overlie on the active surface of the first chip. The liquid insulating adhesive layer is higher than a high of an arc of those first wires and is made of epoxy. Then, a second chip is stacked and aligned on the first chip (step 130) by the insulating adhesive layer. The second chip has an active surface and the active surface is still opposed to the base surface of the multi-chip paddle. Next, a plurality of second wires is bonded between the active surface of the second chip and those leads of the multi-chip paddle (step 132). The process of bonding those second wires can be selected from the group of a normal bonding process and a reverse bonding process. If the module is a two-chip module, the following step is a molding process (step 160).

If the module is a multi-chip module (more than two chips), the following step is to form a liquid insulating adhesive layer on the second chip (step 152) to completely cover the second chip and those second wires which overlie on the active surface of the second chip. The liquid insulating adhesive layer is higher than a high of an arc of those second wires and is made of epoxy. Then, a third chip is stacked and aligned on the second chip (step 140) by the insulating adhesive layer. The third chip has an active surface and the active surface is still opposed to the base surface of the multi-chip paddle. Next, a plurality of third wires are bonded between the active surface of the third chip and those leads of the multi-chip paddle (step 142). Last, the molding process (step 162) is performed to complete the product.

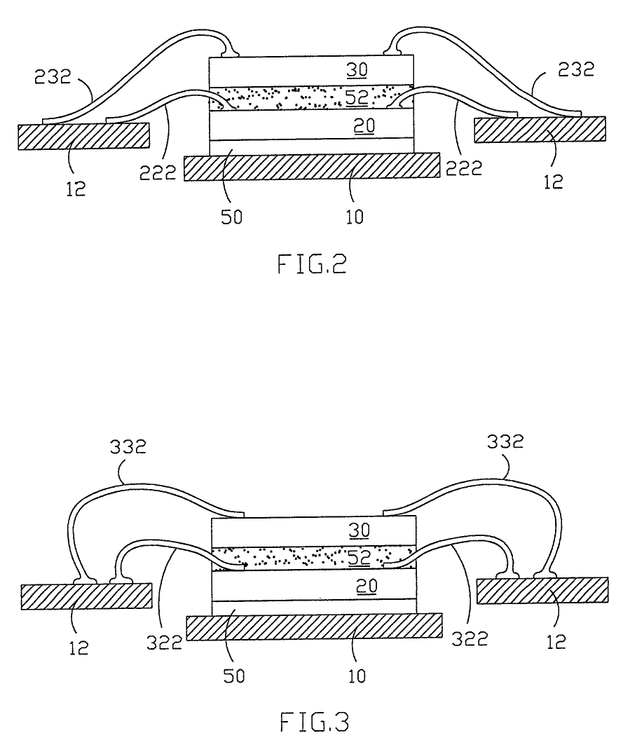

Referring to FIG. 2, there is an embodiment in the present invention. Here, the paddle is used the leadframe type paddle 10 having a plurality of leads 12. The adhesive layer 50 is used to mount the first chip 20 on the leadframe paddle 10. A plurality of first wires 222 are bonded between an active surface of the first chip 20 and those leads 12. A liquid insulating adhesive layer 52 is formed-to cover the active surface of the first chip 10 and those first wires 222 thereon, wherein the liquid insulating adhesive layer 52 is higher than a high of an arc of those first wires. A second chip 30 is stacked and aligned on the first chip 20 by the liquid insulating adhesive layer 52. A plurality of second wires 232 are bonded between an active surface of the second chip 30 and those leads 12. Those first wires 222 and those wires 232 are formed by using a normal bonding process. The liquid insulating adhesive layer 52 complete fill the space between chips and cover those first wires 222 bonded on the first chip 20. The active surface of the first chip 20 and the active surface of the second chip 30 are both faced up and opposed to the leadframe paddle 10.

FIG. 3 and FIG. 4 are another embodiments in the present invention. Same emblems indicate same elements in different figures. The difference between FIG. 2 and FIG. 3 is that those first wires 322 and those second wires 332 are formed by using a reverse bonding process. Furthermore, the embodiment of FIG. 4 is using a reverse bonding process to form those first wires 422 and using a normal bonding process to form those second wires 432.

Referring to FIG. 5, an embodiment of three chips stack package is provided. There are further comprises an liquid insulating adhesive layer 54 to stack a third chip 40 aligned on the second chip 30. In this embodiment, those first wires 522, second wires 532, and third wires 542 are formed by using a reverse bonding process. The liquid insulating adhesive layer 54 complete fill the space between the second chip 30 and the third chip 40, wherein the liquid insulating adhesive layer 54 is higher than a high of an arc of those second wires 532.

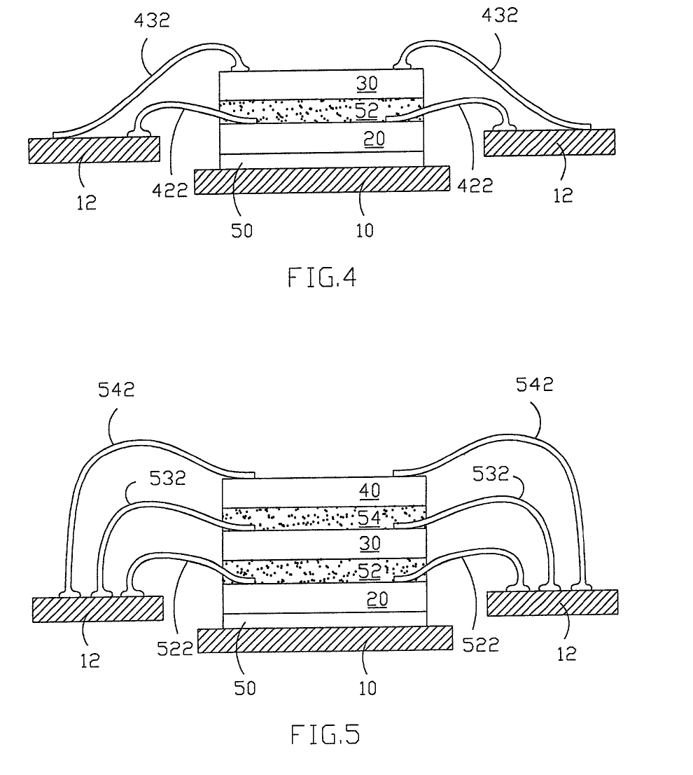

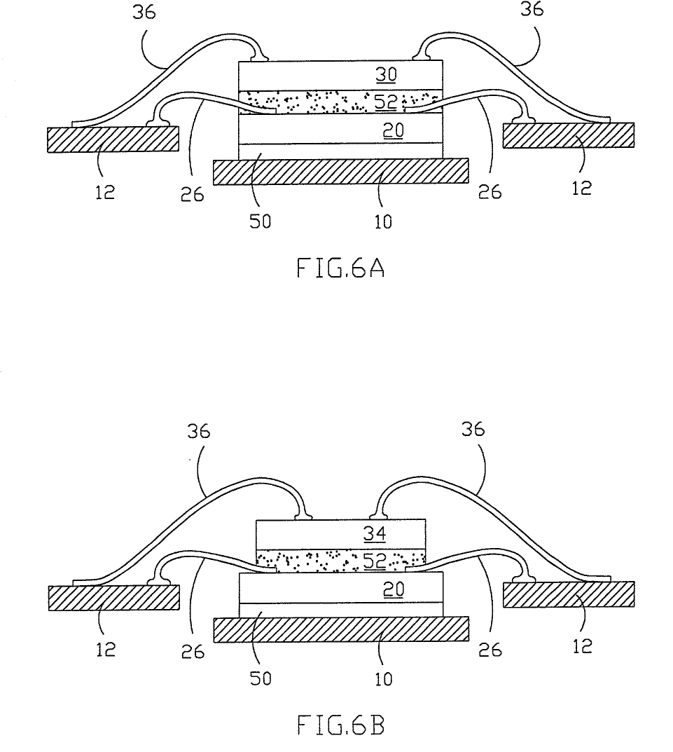

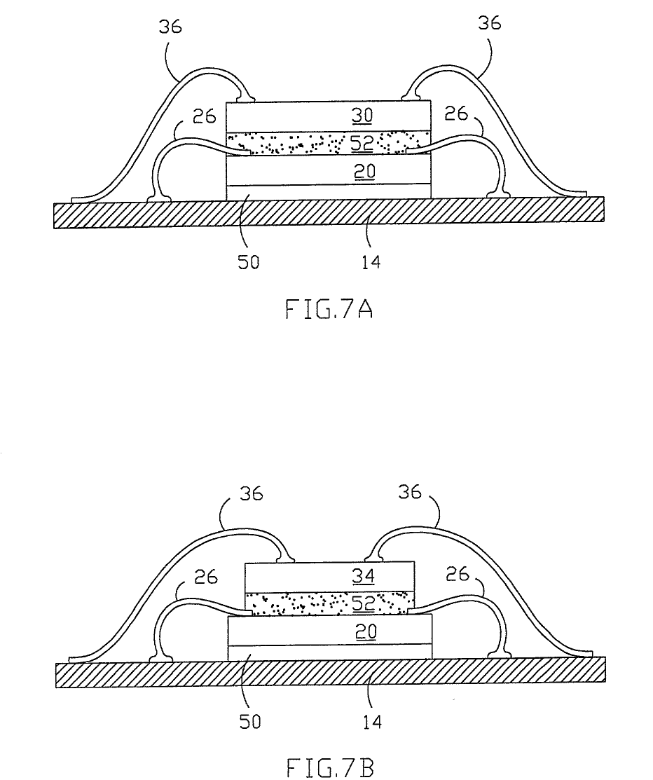

Comparing FIG. 6A and FIG. 6B, the present invention can apply for stack packing different size or function chips. For example, the second chip 34 is different size to the first chip 20, as shown in FIG. 6B. The process of bonding those first wires 26 and second wires 36 can be selected from the group of a normal bonding process and a reverse bonding process. Further comparing FIG. 7A and FIG. 7B, the present invention can still apply for using a substrate type paddle 14.

The present method effectively improves disadvantages of conventional method. The present invention combines a liquid insulating epoxy and a reverse bonding method to improve the stacked die technology. The process technology is easy and low cost. The liquid insulating epoxy completely fills the space between chips and higher than the high of the arc of those wires, so the liquid insulating epoxy can protect the below chip surface and those metal wires thereon, and can increase the reliability of bonding. The present invention can minimize the stacking high by using the reverse bonding process to bond wires, so the present invention can easily stack three chips.

To sum of the forgoing, the present invention provided a structure and a method for multi-chip stack package. Chips are mounted on the same side of the die paddle and active surfaces are all opposed to the die paddle. The die paddle can be made of a leadframe paddle or a substrate paddle. The adhesive layer can use the liquid insulating adhesive layer. The liquid insulating adhesive layer is formed by using a one-step covering process or a step-by-step covering process. The normal bond or the reverse bond method can selectively use here. The present invention can apply for stacking same or different size chips, apply for same or different function chips, and stacking more than two chips.

Of course, it is to be understood that the invention need not be limited to these disclosed embodiments. Various modification and similar changes are still possible within the spirit of this invention. In this way, the scope of this invention should be defined by the appended claims.

What is claimed is:

1. A method for forming a multi-chip module, said method comprising:
providing a multi-chip paddle, wherein said multi-chip paddle having a base surface;
mounting a first chip on said base surface of said multi-chip paddle, wherein an active surface of said first chip is opposed to said base surface of said multi-chip paddle;
bonding a plurality of first wires between said active surface of said first chip and a plurality of leads of said multi-chip paddle;
forming a liquid insulating adhesive layer to completely cover said active surface of said first chip and said first wires bonded thereon, wherein said liquid insulating adhesive layer is higher than a high of an arc of said first wires;
stacking a second chip aligned on said first chip by using said liquid insulating adhesive layer, wherein an active surface of said second chip is opposed to said base surface of said multi-chip paddle; and
bonding a plurality of second wires between said active surface of said second chip and said leads of said multi-chip paddle.

2. The method according to claim 1, wherein said multi-chip paddle is a leadframe paddle.

3. The method according to claim 1, wherein said multi-chip paddle is selected from the group consisting of an organic substrate, a ceramic substrate, and a metal substrate.

4. The method according to claim 1, wherein the cover range on said first chip comprises a bonding wire area of said first chip.

5. The method according to claim 1, wherein the process of bonding said first wires is selected from the group consisting of a normal bonding process and a reverse bonding process.

6. The method according to claim 1, wherein the process of bonding said second wires is selected from the group consisting of a normal bonding process and a reverse bonding process.

7. A method for forming a multi-chip module, said method comprising:
providing a multi-chip paddle, wherein said multi-chip paddle having a base surface;
mounting a first chip on said base surface of said multi-chip paddle, wherein an active surface of said first chip is opposed to said base surface of said multi-chip paddle;
bonding a plurality of first wires between said active surface of said first chip and a plurality of leads of said multi-chip paddle;
forming a first liquid insulating adhesive layer to completely cover said active surface of said first chip and said first wires bonded on said active surface of said first chip, wherein said first liquid insulating adhesive layer is higher than a high of an arc of said first wires;
stacking a second chip aligned on said first chip by using said first liquid insulating adhesive layer, wherein an active surface of said second chip is opposed to said base surface of said multi-chip paddle;
bonding a plurality of second wires between said active surface of said second chip and said leads of said multi-chip paddle;
forming a second liquid insulating adhesive layer to completely cover said active surface of said second chip and said second wires bonded thereon, wherein said second liquid insulating adhesive layer is higher than a high of an arc of said second wires;
stacking a third chip aligned on said second chip by using said second liquid insulating adhesive layer, wherein an active surface of said second chip is opposed to said base surface of said multi-chip paddle; and
bonding a plurality of third wires between said active surface of said third chip and said leads of said multi-chip paddle.

8. The method according to claim 7, wherein said multi-chip paddle is a leadframe paddle.

9. The method according to claim 7, wherein said multi-chip paddle is selected from the group consisting of an organic substrate, a ceramic substrate, and a metal substrate.

10. The method according to claim 7, wherein the cover range on said first chip comprises a bonding wire area of said first chip.

11. The method according to claim 7, wherein the cover range on said second chip comprises a bonding wire area of said second chip.

12. The method according to claim 7, wherein the process of bonding said first wires is selected from the group consisting of a normal bonding process and a reverse bonding process.

13. The method according to claim 7, wherein the process of bonding said second wires is selected from the group consisting of a normal bonding process and a reverse bonding process.

14. The method according to claim 7, wherein the process of bonding said third wires is selected from the group consisting of a normal bonding process and a reverse bonding process.

15. A multi-chip module comprising:
a multi-chip paddle, wherein said multi-chip paddle having a base surface;
a first chip mounted on said base surface of said multi-chip paddle, wherein an active surface of said first chip is opposed to said base surface of said multi-chip paddle;
a plurality of first wires bonded between said active surface of said first chip and a plurality of leads of said multi-chip paddle;
a liquid insulating adhesive layer completely covering said active surface of said first chip and said first wires bonded thereon, wherein said liquid insulating adhesive layer is higher than a high of an arc of said first wires;
a second chip stacked and aligned on said first chip by said liquid insulating adhesive layer, wherein an active surface of said second chip is opposed to said base surface of said multi-chip paddle; and
a plurality of second wires bonded between said active surface of said second chip and said leads of said multi-chip paddle.

16. The multi-chip module according to claim 15, wherein the process of bonding said first wires is selected from the group consisting of a normal bonding process and a reverse bonding process.

17. The multi-chip module according to claim 15, wherein the process of bonding said second wires is selected from the group consisting of a normal bonding process and a reverse bonding process.

18. The multi-chip module according to claim 15, wherein the cover range on said first chip comprises a bonding wire area of said first chip.

19. A multi-chip module comprising:
a multi-chip paddle, wherein said multi-chip paddle having a base surface;
a first chip mounted on said base surface of said multi-chip paddle, wherein an active surface of said first chip is opposed to said base surface of said multi-chip paddle;
a plurality of first wires bonded between said active surface of said first chip and a plurality of leads of said multi-chip paddle;
a first liquid insulating adhesive layer completely covering said active surface of said first chip and said first wires bonded thereon, wherein said first liquid insulating adhesive layer is higher than a high of an arc of said first wires;
a second chip stacked and aligned on said first chip by said first liquid insulating adhesive layer, wherein an active surface of said second chip is opposed to said base surface of said multi-chip paddle;
a plurality of second wires bonded between said active surface of said second chip and said leads of said multi-chip paddle;
a second liquid insulating adhesive layer completely covering said active surface of said second chip and said second wires bonded thereon, wherein said second liquid insulating adhesive layer is higher than a high of an arc of said second wires;
a third chip stacked and aligned on said second chip by said second liquid insulating adhesive layer, wherein an active surface of said second chip is opposed to said base surface of said multi-chip paddle; and
a plurality of third wires bonded between said active surface of said third chip and said leads of said multi-chip paddle.

20. The multi-chip module according to claim 19, wherein the process of bonding said first wires is selected from the group consisting of a normal bonding process and a reverse bonding process.

21. The multi-chip module according to claim 19, wherein the process of bonding said second wires is selected from the group consisting of a normal bonding process and a reverse bonding process.

22. The multi-chip module according to claim 19, wherein the process of bonding said first wires is selected from the group consisting of a normal bonding process and a reverse bonding process.

23. The multi-chip module according to claim 19, wherein the cover range on said first chip comprises a bonding wire area of said first chip.

24. The multi-chip module according to claim 19, wherein the cover range on said second chip comprises a bonding wire area of said second chip.
